(19) United States
(12) Patent Application Publication
(10) Pub. No.: US 2015/0179557 A1
(43) Pub. Date: Jun. 25, 2015

(54) SEMICONDUCTOR CHIPS HAVING HEAT CONDUCTIVE LAYER WITH VIAS

(71) Applicant: INTERNATIONAL BUSINESS MACHINES CORPORATION, Armonk, NY (US)

(72) Inventors: Kenneth J. Goodnow, Essex Junction, VT (US); Richard S. Graf, Gray, ME (US); Clarence R. Ogilvie, Huntington, VT (US); Sebastian T. Ventrone, South Burlington, VT (US); Charles S. Woodruff, Charlotte, VT (US)

(73) Assignee: INTERNATIONAL BUSINESS MACHINES CORPORATION, Armonk, NY (US)

(21) Appl. No.: 14/138,022

(22) Filed: Dec. 21, 2013

(51) Int. Cl. H01L 23/498; H01L 25/065; H01L 23/00

(52) U.S. Cl. CPC H01L 23/49811; H01L 23/49827; H01L 24/14; H01L 25/0657; H01L 2224/1401

(57) ABSTRACT

A heat conductive layer is deposited on a first surface of a wafer of semiconductor chips. The heat conductive layer is etched to form vias that expose through-electrodes on the first surface of each semiconductor chip. Conductive bumps are deposited on the through-electrodes on a second surface of each semiconductor chip. The semiconductor chips are stacked, wherein the conductive bumps of a second one of the semiconductor chips electrically contact the through-electrodes of a first one of the semiconductor chips through the vias of the first semiconductor chip and the conductive bumps of a third one of the semiconductor chips electrically contact the through-electrodes of the second semiconductor chip through the vias of the second semiconductor chip.

### FIELD OF THE INVENTION

The present invention relates to a semiconductor chip and a method for fabricating the same. The present invention also relates to a package of such chips and a method for fabricating or assembling the package.

### BACKGROUND

As shown in FIG. 1, a semiconductor chip 100 has a surface 110 with conductive bumps 124 for connections to circuitry of chip 100. A heat conductive plate 130 is provided for placement on surface 110, as shown in FIG. 2. Plate 130 forms vias 140 corresponding to bumps 120, where it is intended that bumps 120 do not contact or, worse still, overlap plate 130. However, avoiding contact and overlap between bumps 120 and plate 130 requires proper alignment. As shown in FIG. 2, a small amount of misalignment of plate 130 may result in contact between plate 130 and one or more bumps 120.

Objects, advantages and novel features of the present invention are set out in, and will become apparent to persons of skill in the art from, the following description and by practice of the invention, wherein the objects, advantages and features may be attained by what is pointed out in the appended claims.

### SUMMARY

According to one or more embodiments of the present invention, a semiconductor package includes a substrate having a first surface, a second surface opposing the first surface, and first bonding pads disposed on the second surface. The package further includes a first semiconductor chip having a third surface facing the second surface of the substrate, a fourth surface opposing the third surface, and first through-electrodes extending between the third and fourth surfaces. Respective ones of the first through-electrodes correspond to, and are electrically connected to, respective ones of the first bonding pads. A first heat conductive layer is plated onto the fourth surface, thereby providing a fifth surface.

In another aspect, a first insulating layer is formed on the first heat conductive layer fifth surface, thereby providing a sixth surface, wherein the first heat conductive layer and first insulating layer form first vias, respective ones of the first vias surrounding respective ones of the first through-electrodes. Further, the package includes a second semiconductor chip having a seventh surface facing the sixth surface of the first insulating layer of the first semiconductor chip, an eighth surface opposing the seventh surface, and second through-electrodes extending between the seventh and eighth surfaces. Respective ones of the second through-electrodes correspond to, and have electrical connections through the first vias to, respective ones of the first through-electrodes of the first semiconductor chip.

According to one or more embodiments of the present invention, a method of providing a package of semiconductor chips includes plating a heat conductive layer on a first surface of a wafer of semiconductor chips, the wafer having a second surface opposing the first surface. The first and second surfaces of the wafer provide first and second opposing surfaces for each semiconductor chip and the plating of the first surface of the wafer thereby plates the first surfaces of the respective semiconductor chips. The method further includes forming an insulating layer on the heat conductive layer and etching the heat conductive layer, wherein each semiconductor chip has through-electrodes extending between the semiconductor chip's first and second surfaces and the etching includes etching vias that expose the through-electrodes on the first surface of each semiconductor chip.

In an additional aspect, conductive bumps are deposited on the through-electrodes on the second surface of each semiconductor chip. The semiconductor chips are diced from the wafer and a first, second and third one of the semiconductor chips are stacked, wherein the conductive bumps of the second semiconductor chip electrically contact the through-electrodes of the first semiconductor chip through the vias of the first semiconductor chip and the conductive bumps of the third semiconductor chip electrically contact the through-electrodes of the second semiconductor chip through the vias of the second semiconductor chip.

According to one or more embodiments of the present invention, a method includes placing a first semiconductor chip on a substrate having a first surface, a second surface opposing the first surface, and first bonding pads on the second surface, wherein the first semiconductor chip has a third surface, a fourth surface opposing the third surface, first through-electrodes extending between the third and fourth surfaces, and conductive bumps on the third surface.

In another aspect, placing the first semiconductor chip on the substrate includes placing the first semiconductor chip with respective conductive bumps of the first semiconductor chip contacting respective ones of the first bonding pads. Further, the method includes attaching respective conductive bumps of the first semiconductor chip to respective ones of the first bonding pads. A second semiconductor chip is placed on the first semiconductor chip, wherein the first semiconductor chip further has a first heat conductive layer plated onto the fourth surface, thereby providing a fifth surface, and the first semiconductor chip further has a first insulating layer formed on the first heat conductive layer fifth surface, thereby providing a sixth surface.

In a further aspect, the first heat conductive layer and first insulating layer form first vias, respective ones of the first vias exposing respective ones of the first through-electrodes of the first semiconductor chip, wherein the second semiconductor chip has a seventh surface, an eighth surface opposing the seventh surface, second through-electrodes extending between the seventh and eighth surfaces, and conductive bumps on the seventh surface. Placing the second semiconductor chip on the first semiconductor chip includes placing the second semiconductor chip with respective conductive bumps of the second semiconductor chip in electrical contact with respective ones of the first semiconductor chip's through-conductors through the first vias.

Additionally, the method includes attaching the second semiconductor chip to the first semiconductor chip such that respective conductive bumps of the second semiconductor chip maintain fixed electrical contact with the respective ones of the first semiconductor chip's through-conductors through the first vias.

### BRIEF DESCRIPTION OF THE FIGURES

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 illustrates a semiconductor chip surface and a heat conductive plate for placement thereon, according to the prior art.

FIG. 2 illustrates an alignment issue relating to placement of the heat conductive plate on the semiconductor chip, according to the prior art.

FIGS. 3A through 3F illustrate structure of a semiconductor chip in stages of fabrication and illustrate associated processing actions of the stages, according to one or more embodiments of the present invention.

FIG. 3G provides a view of one side of the semiconductor chip of FIG. 3F, according to one or more embodiments of the present invention.

FIG. 3H illustrates the view of the one side of the semiconductor chip of FIG. 3F, wherein a layer is separated into portions, according to one or more embodiments of the present invention.

FIGS. 4A through 4D illustrate structure of a semiconductor chip package in stages of fabrication or assembly and illustrate associated processing actions of the stages, according to one or more embodiments of the present invention.

FIG. 4E illustrates additional details of one of the semiconductor chips of the package shown in FIGS. 4A through 4D, according to one or more embodiments of the present invention.

FIG. 5 illustrates a semiconductor chip package utilizing adhesive films, according to one or more embodiments of the present invention.

FIG. 6 illustrates a semiconductor chip package utilizing conductive pillars, according to one or more embodiments of the present invention.

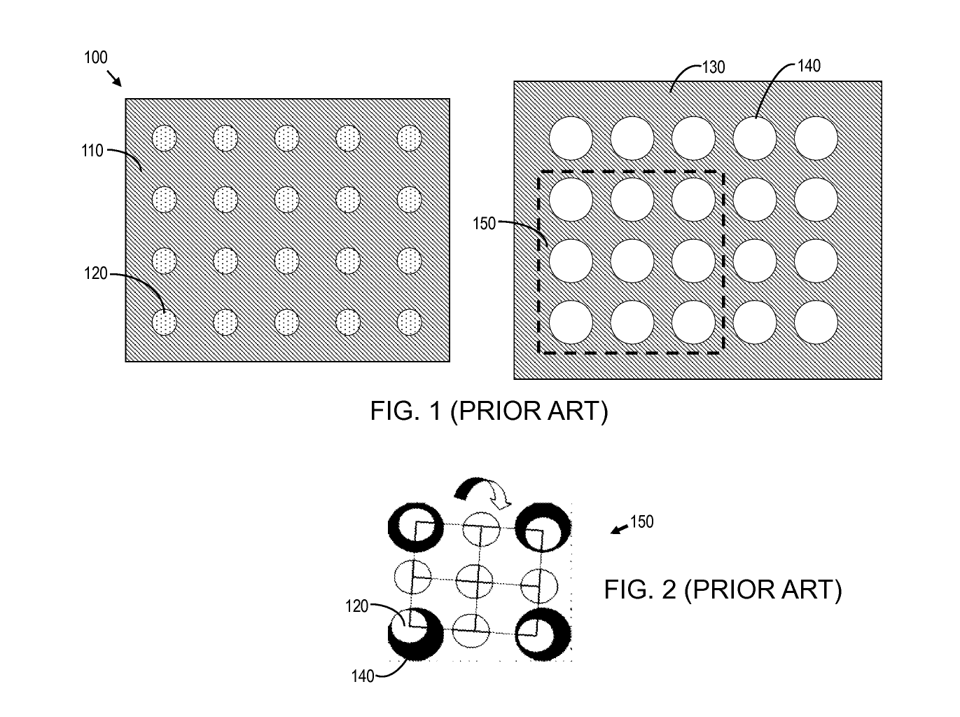

### DETAILED DESCRIPTION

Descriptions of various embodiments of the present invention are herein presented for purposes of illustration, but are not intended to be exhaustive or limited to the embodiments disclosed. Many modifications and variations will be apparent to persons of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Method aspects described herein are used in fabrication of integrated circuit chips. Resulting integrated circuit chips can be distributed by a fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

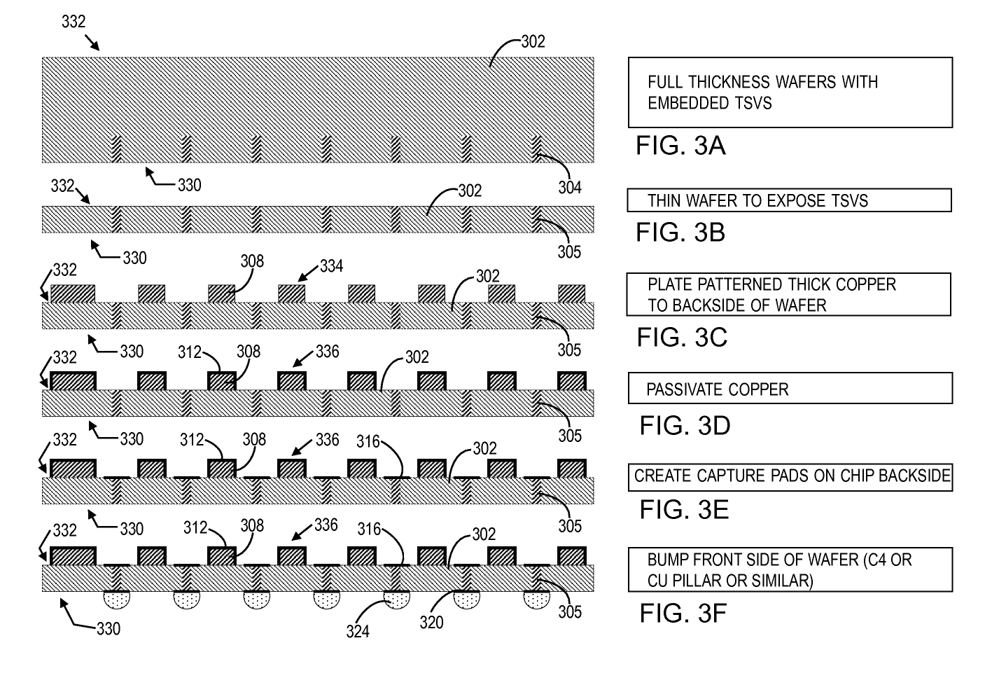

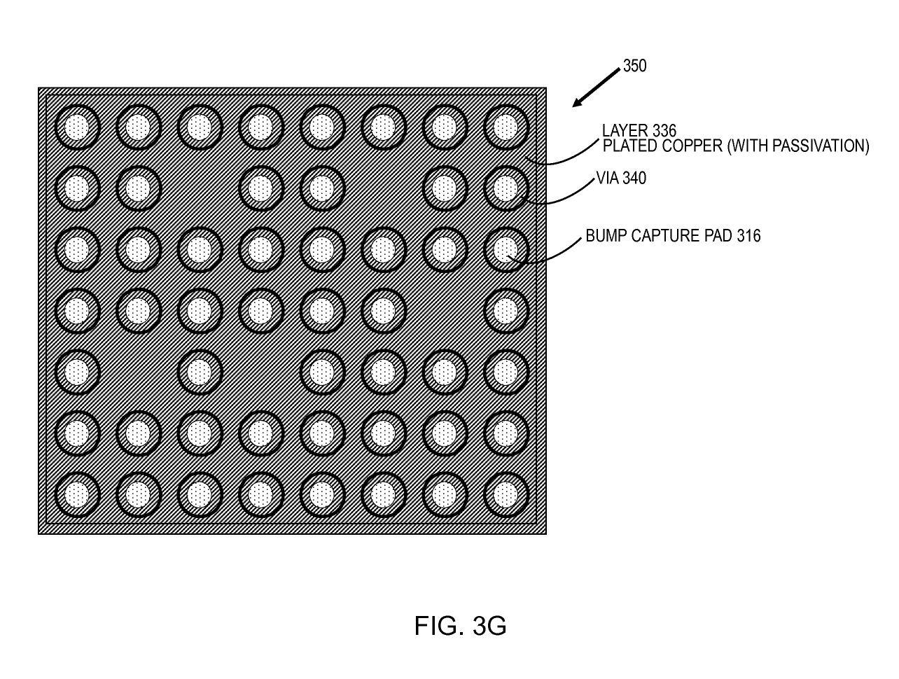

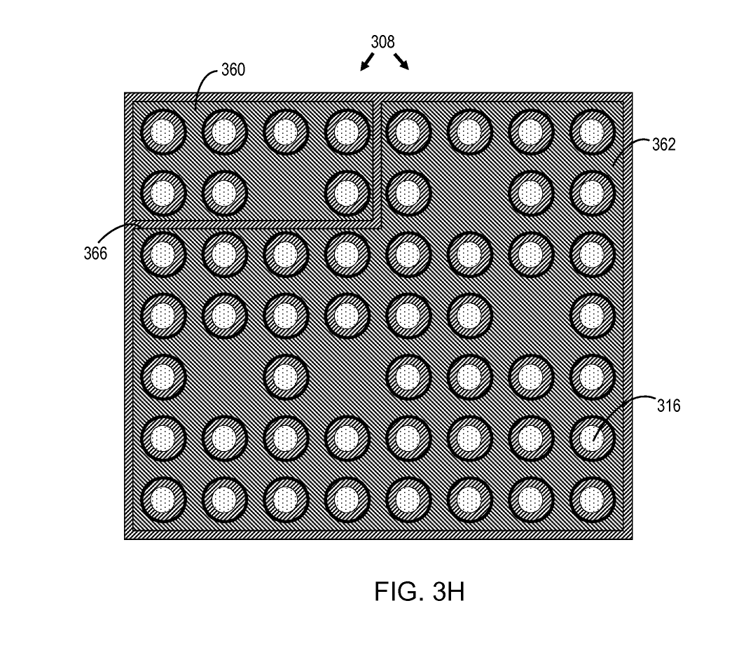

For providing a package of semiconductor chips, individual semiconductor chips are fabricated as illustrated in FIGS. 3A through 3G, according to embodiments of the present invention. As shown in FIG. 3A, full thickness wafer 302 is provided, which may include one or more materials such as silicon. For example, 200 mm wafers may be 725 um thick and 300 mm wafers may be 775 um thick. Wafer 302 has first surface 330 and second surface 332 opposing surface 330. Narrow channels 304, which may have a substantially uniform round cross-section that is, for example, approximately 5 to 100 um in diameter, are formed on one of the surfaces 330 or 332 and extending inward, i.e., toward the other one of the surfaces 330 or 332, such as formed on surface 330 extending 10 to 100 um toward surface 332, as shown in one or more embodiments illustrated by FIG. 3A. Channels 304 may include one or more electrically conductive materials, such as copper or tungsten, and may be formed such as by etching the via and depositing the conductive material surrounding by insulating material.

As shown in FIG. 3B, wafer 302 is then thinned, such as to a thickness of 10 um to 100 um, so that channels 304 are exposed on both surface 332 and surface 330 to provide electrically conductive, through-silicon vias 305 extending all the way from one surface 332 to the other surface 332. Accordingly, exposed ends of the through-silicon vias 305 form part of surfaces 330 and 332. The thinning of wafer 302 may be done by processes including mechanical grinding or chemical mechanical polish, for example.

As shown in FIG. 3C, on one of the surfaces, such as surface 332 as shown in the figure, a heat conductive layer 308, is formed, which may initially cover through-silicon vias 305, in which case layer 308 is then etched via chemical or plasma to expose the vias 305. As shown in FIG. 3G, the etching may form round vias 340 in heat conductive layer 308. Heat conductive layer 308 may be formed by plating one or more materials including copper, aluminum or similar thermal conductive material. Electroplating is one way of performing the plating operation. Wafer 302 will ultimately be diced into individual semiconductor chips. (Stated another way, semiconductor chips will be diced from wafer 302.) Accordingly, the plating of the one surface 332 of wafer 302 thereby plates one of the surfaces of the respective semiconductor chips that are diced therefrom. Only one such chip 350 is shown in FIGS. 3A through 3G.

The present invention involves a recognition that plating heat conducting layer 308 on surface 332 and then etching vias 340 to expose through-silicon vias 305 allows for more precise control of via 340 centering relative to vias 305 and of via 340 sizes. As shown, through silicon vias 305 may be uniform in diameter and openings 340 may be, correspondingly, uniform in diameter, although larger. For example, for via 305 diameters of 5 to 100 um, the diameters of vias 340 in conductive layer 308 may be 10 to 200 um, i.e., vias 340 may be approximately twice the size of vias 305. And for example, etching enables precise placement of openings 340, such that each opening 340 is substantially centered on the center of its respective through-silicon via 305, e.g., centered on vias 305 with a precision of 1 to 5 um.

As shown in FIG. 3D, an insulating layer 312 is formed on the etched, heat conductive layer 308, such as by oxidation of a copper heat conductive layer 308, for example, which passivates the copper of etched layer 308. Insulating layer 312 may be, for example, 0.2 to 2 um. In alternative embodiments, the etching of vias 340 described above may be performed after adding insulating layer 312. In one or more embodiments of the present invention wherein the above described etching precedes formation of insulating layer 312, the above described sizes of openings 340 may be adjusted to account for the addition of layer 312 which will make openings 340 smaller in diameter by a factor substantially equal to twice the thickness of insulating layer 312.

As shown in FIG. 3E, conductive pads are deposited on the exposed ends of through-silicon electrodes 305, i.e., conductive pads 320 on the surface 330 side of each chip in wafer 302 and conductive pads 316 within vias 340 (FIG. 3G) on the surface 332 side. Conductive pads 316 and 320 may include one or more materials, such as copper, nickel and gold, and may be deposited by one or more processes such as sputtering and electroplating to a thickness of 0.5 to 4 um, for example. Pads 316 within vias 340 may be referred to herein as “capture pads,” since they provide a surface that solder can reflow and join with, to capture conductive bumps of semiconductor chips placed thereon, as described further herein below.

Although round pads 316 are illustrated in FIG. 3G, pads 316 and 320 may include pads of regular shapes, pads of irregular shapes or pads of both regular and irregular shapes. Likewise, although through-silicon vias 305 may have round cross-sections in a plane parallel to that shown in FIG. 3G, vias 305 may include vias of regular shapes, vias of irregular shapes or vias of both regular and irregular shapes. For example, vias may be donut or bar shaped, for example.

Conductive bumps 324 are deposited on conductive pads 320, which are on the exposed ends of through-electrodes 305 of surface 330 of each semiconductor chip in wafer 302, as shown in FIG. 3F. Bumps 423 may include one or more materials, such as lead, copper, tin and silver, and may be deposited by one or more processes such as sputtering and electroplating to a thickness of 10 to 100 um, for example. These solder bumps may include additional materials, referred to as under bump metallurgy, that improve adhesion between the solder and the wafer 302. This under bump metallurgy can include one or more materials such as titanium, tungsten, copper and nickel, or similar.

The actions described herein above for FIGS. 3A through 3G result in a semiconductor chip 350, as shown in FIG. 3F. It should be appreciated that since pads 320, through-electrodes 305 and pads 316 are electrically conductive, according to the above described structure of chip 350 conductive bumps 324 of semiconductor chip 350 are in electrical contact with conductive pads 320, through-electrodes 305 and conductive pads 316, thereby providing respective electrical paths through chip 350 from one side 330 to the other side 332. In one or more embodiments of the present invention, one or both of pads 316 and 320 may be omitted, while still maintaining the electrical paths through chip 350. For example, conductive bumps 324 may be formed directly on conductive material of through silicon vias 305.

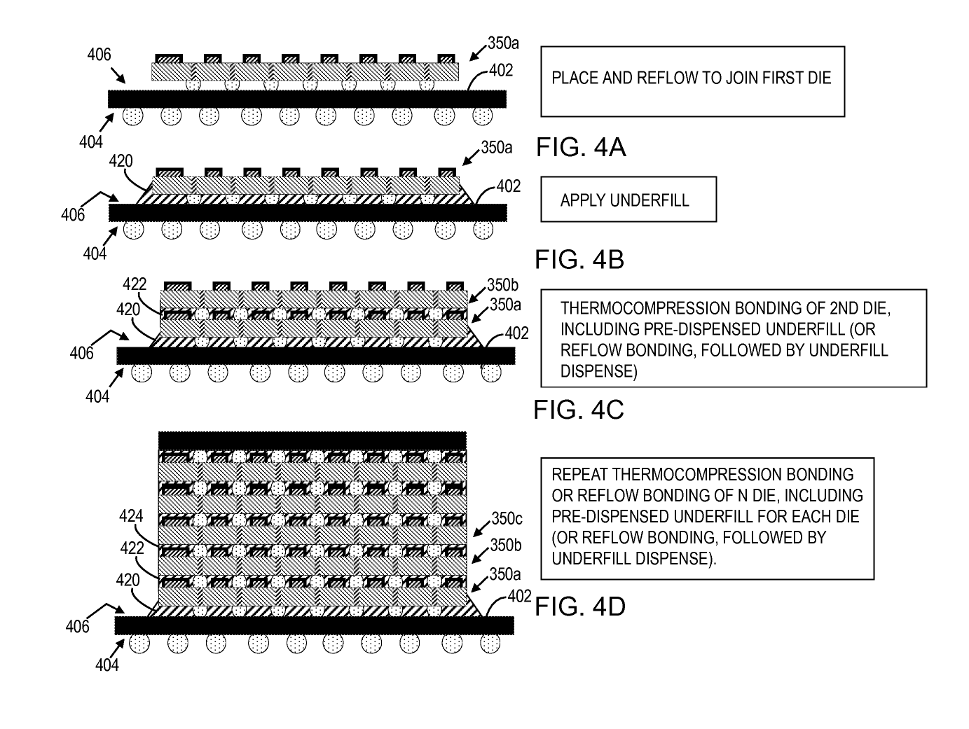

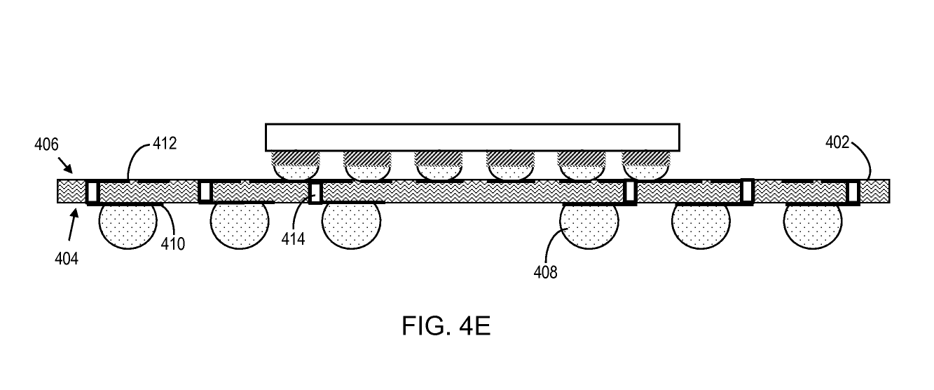

Referring now to FIGS. 4A through 4E, for chips such as chips 305 of FIGS. 3F and 3G, a process and structure of stacking chips is illustrated, according to embodiments of the present invention, wherein a first one of semiconductor chips 350 of FIGS. 3F and 3G is referred to as chip 350a, a second of such semiconductor chips 350 is referred to as chip 350b, etc. Likewise, individual parts of a semiconductor chip 350 of FIGS. 3F and 3G are referred to in FIGS. 4A through 4E by the suffix “a” for chip 350a, the suffix “b” for chip 350b, etc.

In general terms, the process and structure illustrated by FIGS. 4A through 4E includes providing a first one of the semiconductor chips 350a and stacking a second of the semiconductor chips 350b on the first semiconductor chip 350a (FIG. 4C). Further, a third one of the semiconductor chips 350c is stacked on the second semiconductor chip 350b (FIG. 4D), etc. The stacking is done such that conductive bumps 324b of second semiconductor chip 350b electrically contact through-electrodes 305a of first semiconductor chip 350a through vias 340a of first semiconductor chip 350a. That is, for embodiments such as shown in FIG. 3F, in which conductive pads 316 are deposited on through-electrodes 305, conductive bumps 324b of second semiconductor chip 350b mechanically contact conductive pads 316a of first semiconductor chip 350a, which are in electrical contact with through-electrodes 305a, conductive pads 320a and conductive bumps 324a of first semiconductor chip 350a. Likewise, conductive bumps 324c of third semiconductor chip 350c electrically contact through-electrodes 305b of second semiconductor chip 350b through vias 340b of second semiconductor chip 350b, etc.

Also in general terms, the example of FIGS. 4A through 4E includes bonding the first chip's conductive pads 316a to the second chip's conductive bumps 324b (FIG. 4C) and bonding the second chip's conductive pads 316b to the third chip's conductive bumps 324c, etc. (FIG. 4D), which may be by thermo compression bonding, for example. Alternatively, the bonding may be by placing one chip on top of another and reflowing them, for example. Further, a substrate 402 is provided and the semiconductor chips 350a, 350b, 350c, etc. are stacked on the substrate.

Referring now to FIG. 4E, details of substrate 402 are illustrated, according to one or more embodiments of the present invention. Substrate 402 has a first surface 404, a second surface 406 opposing first surface 404, bonding surfaces 410 disposed on first surface 404 and bonding surfaces 412 disposed on second surface 406. As shown in FIG. 4E, bonding surfaces 410 and 412 have irregular shapes. However, bonding surfaces 410 may have regular shapes, irregular shapes or both regular and irregular shapes. Likewise, bonding surfaces 412 may have regular shapes, irregular shapes or both regular and irregular shapes.

Substrate 402 includes a core, of which the first and second surfaces 404 and 406 are opposing faces. Bonding surfaces 410 and 412 may be solder coated copper, where the copper may be plated on respective surfaces 404 and 406 and connected to copper-plated through-connections, e.g., connections 414, which may be formed by copper plating of holes through substrate 402, where the holes may be formed such as by laser or mechanical drilling. Substrate 402 also includes conductive bumps 408 respectively disposed on bonding surfaces 410.

As shown in FIGS. 4D and 4E, the illustrated process may further include depositing bonding pads 412 on substrate 402 and bonding conductive bumps 324a of first chip 350a to bonding pads 412. The core of substrate 402 may include one or more of materials such as fiberglass and resin FR-4 or similar. Substrate 402 may be a two layer laminate, for example, with a copper routing layer on top, that is, proximate to surface 406, and another copper routing layer on bottom, that is, proximate to surface 404. Substrate 402 may include additional routing layers to accommodate additional routing complexity.

In particular, the process and structure illustrated in FIGS. 4A through 4E include placing (FIG. 4A) a first semiconductor chip 350a on a substrate 402 having a first surface 404, a second surface 406 opposing first surface 404, and bonding pads 412 on second surface 406. (In this description, once again, a first one of semiconductor chips 350 of FIG. 3F is referred to as chip 350a, a second of semiconductor chips 350 of FIG. 3F is referred to as chip 350b, etc., and individual parts of semiconductor chip 350 shown in FIGS. 3F and 3G are referred to by the suffix “a” for chip 350a, the suffix “b” for chip 350b, etc.

First semiconductor chip 350a has a third surface 330a, a fourth surface 332a opposing third surface 330a, first, conductive through-electrodes 305a extending between third and fourth surfaces 330a and 332a, and conductive bumps 324a on third surface 330a. Placing (FIG. 4A) first semiconductor chip 350a on substrate 402 includes placing chip 350a with respective conductive bumps 324a of chip 350a contacting respective ones of the bonding pads 412 and attaching respective conductive bumps 324a to respective ones of the bonding pads 412.

Further, a second semiconductor chip 350b is placed (FIG. 4C) on first semiconductor chip 350a, wherein chip 350a has a first heat conductive layer 308a plated onto fourth surface 332a, thereby providing a fifth surface, and chip 350a further has a first insulating layer 312a formed on heat conductive layer/fifth surface 308a, thereby providing a sixth surface. Heat conductive layer 308a and insulating layer 312a form first vias 340a, respective ones of first vias 340a exposing respective ones of first through-electrodes 305a of first semiconductor chip 350a, wherein second semiconductor chip 350b has a seventh surface 330b, an eighth surface 332b opposing seventh surface 330b, second through-electrodes 305b extending between the seventh and eighth surfaces 330b and 332b, and conductive bumps 324b on seventh surface 330b.

Placing (FIG. 4C) second semiconductor chip 350b on first semiconductor chip 350a includes placing second semiconductor chip 350b with respective conductive bumps 324b of chip 350b in electrical contact with respective ones of the first semiconductor chip's through-conductors 305a through first vias 340a. The disclosed method includes attaching second semiconductor chip 350b to first semiconductor chip 350a such that respective conductive bumps 324b of second chip 350b maintain fixed electrical contact with respective ones of the first chip's through-conductors 305a through first vias 340a.

The disclosed method and structure further includes placing (FIG. 4D) a third semiconductor chip 350c on second semiconductor chip 350b, wherein second semiconductor chip 350b has a second heat conductive layer 308b plated onto the eighth surface of second semiconductor chip 350b, thereby providing a ninth surface, and has a second insulating layer 312b formed on the second heat conductive layer/ninth surface 308b, thereby providing a tenth surface, wherein second heat conductive layer 308b and second insulating layer 312b form second vias 340b, respective ones of second vias 340b surrounding respective ones of the second through-electrodes 305b of second semiconductor chip 350b.

The third semiconductor chip 350c has an eleventh surface 330c, a twelfth surface 332c opposing eleventh surface 330c, third through-electrodes 305c extending between the eleventh and twelfth surfaces 330c and 332c, and conductive bumps 324c on the eleventh surface 332c. Placing third semiconductor chip 350c on second semiconductor chip 350b includes placing third chip 350c such that respective ones of the third chip's conductive bumps 324c are in electrical contact with respective ones of the second semiconductor chip's through-conductors 305b exposed by second vias 340b. The disclosed method further includes attaching third semiconductor chip 350c to second semiconductor chip 350b, including attaching such that respective ones of the third semiconductor chip's conductive bumps 324c maintain fixed electrical contact with the respective ones of the second semiconductor chip's through-electrodes 305b exposed by second vias 340b.

In one or more embodiments, first semiconductor chip 350a further has respective conductive pads 316a electrically connected to respective first through-electrodes 305a in the first vias 340a, and attaching second semiconductor chip 350b to first semiconductor chip 350a includes attaching second chip's conductive bumps 324b to respective ones of first semiconductor chip's capture pads 316a. Also, second semiconductor chip 350b further has respective conductive pads 316b electrically connected to respective second through-electrodes 305b in second vias 340b, and attaching third chip 350c to second chip 350b, includes attaching the third chip's conductive bumps 324c to respective ones of the second chip's capture pads 316b.

In one or more embodiments, the attaching of the first chip's conductive bumps 324a to respective ones of the first bonding pads 412 of substrate 402, the attaching of the second chip's conductive bumps 324b to respective ones of the first chip's capture pads 316a and the attaching of the third chip's conductive bumps 324c to respective ones of the second chip's capture pads 316c includes attaching by thermo-compression of the conductive bumps 324a, 324b and 324c against bonding pads 412 and conductive pads 316a and 316b and respectively.

In one or more embodiments, conductive bumps 324a have solder coatings and the attaching of the first chip's conductive bumps 324a to respective ones of the first bonding pads 412 of substrate 402, the attaching of the second chip's conductive bumps 324b to respective ones of the first chip's capture pads 316a and the attaching of the third chip's conductive bumps 324c to respective ones of the second chip's capture pads 316b includes attaching by reflowing the solder of the conductive bumps 324a, 324b and 324c.

In one or more embodiments, the disclosed method and structure further comprise applying underfill 420 between first semiconductor chip 350a and substrate 402 (FIG. 4B), underfill 422 between semiconductor chips 350a and 350b (FIG. 4C), underfill 424 between semiconductor chips 350b and 350c, etc. (FIG. 4D), etc. The underfills provide chip-to-chip adhesion (for chip 350b to chip 350a and chip 350c to chip 350b, etc.) and chip-to-substrate adhesion (for chip 350a to substrate 402). The underfills may include one or more materials such as epoxy resin with filler materials, including SiO2 and other materials.

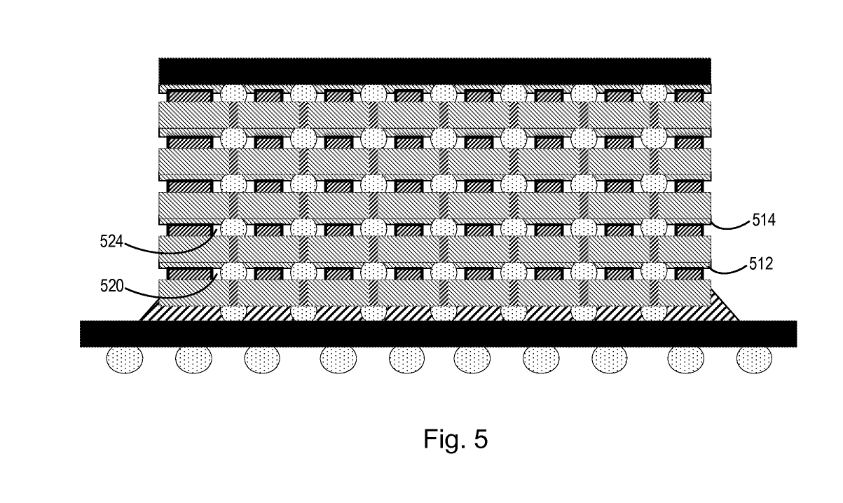

In one or more embodiments, as shown in FIG. 5, the disclosed method and structure further comprises applying, before placing chip 350a (FIG. 4A), chip 350b (FIG. 4C), and 350c (FIG. 4D), respective films 512, 514, etc. of an adhesive material to the respective surfaces 330b and 330c that have the conductive bumps 324b and 324c thereon, such that the respective films provide chip-to-chip adhesion (for chip 350b to chip 350a and chip 350c to chip 350b, etc.) and provide air gaps within vias 340b, i.e., between conductive bumps 324b and insulating layer 312b, between conductive bumps 324c and insulating layer 312c, etc. In such embodiments, chip-to-substrate adhesion (for chip 350a to substrate 402) may be provided by underfill, as previously described.

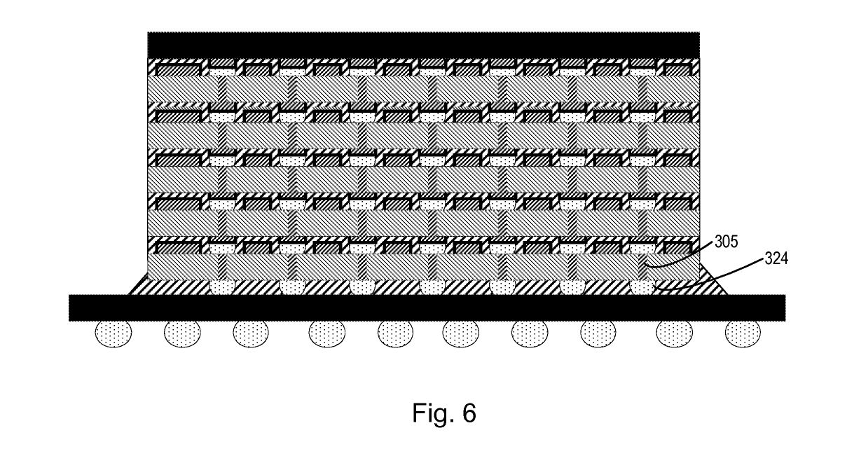

In one or more embodiments, as shown in FIG. 6, for example, the through-electrodes 305 are formed by depositing copper pillars. Copper pillar bumps 324 are provided on electrodes 305 similar to traditional C4 solder bumps, but wherein bump metallurgy includes electroplated or similarly deposited copper to a thickness of 5 um to 50 um with solder deposited on top of the copper to provide a surface that can join to the next level of assembly. Since the copper reflows at a higher temperature than the solder, it provides additional standoff to the bump, which can improve reliability and electrical performance.

Referring now to FIGS. 3F and 3H and, in one or more embodiments, the disclosed method and structure include removing a portion of heat conductive layer 308 of chip 350, such as by etching, to separate layer 308 into at least two portions, such as, for example, a grounding portion 360 and a source voltage portion 362, as shown in the illustrated instance. That is, as shown in FIG. 3H a grounding portion 360 and a source voltage portion 362 of layer 308 are separated by portion 366 that has been removed. At least one conductive pad 316 of semiconductor chip 350 is connected to the grounding portion 360 and at least one other conductive pad 316 of the semiconductor chip 350 is connected to the source voltage portion 362.

While this specification contains many specifics, these should not be construed as limitations on the scope of the invention or of what can be claimed, but rather as descriptions of features specific to particular implementations of the invention. The separation of various components in the implementations described above should not be understood as requiring such separation in all implementations. Certain features that are described in this specification in the context of separate implementations can also be implemented in combination in a single implementation. Conversely, various features that are described in the context of a single implementation can also be implemented in multiple implementations separately or in any suitable sub combination.

Moreover, although features can be described above as acting in certain combinations and even initially claimed as such, one or more features from a claimed combination can in some cases be excised from the combination, and the claimed combination can be directed to a subcombination or variation of a subcombination.

The actions recited in the claims may be performed in a different order and still achieve desirable results in at least some cases. Likewise, the processes depicted in the accompanying figures do not necessarily require the particular order shown, or sequential order, to achieve desirable results, nor do they require that all illustrated operations be performed, to achieve desirable results.

The Figures illustrate architecture, functionality, and operation of possible implementations of apparatus and methods, according to various embodiments of the present invention. Those skilled in the art having read this disclosure will recognize that changes and modifications may be made to the embodiments without departing from the scope of the present invention. It should be appreciated that the particular implementations shown and described herein are illustrative of the invention and its best mode and are not intended to otherwise limit the scope of the present invention in any way. Other variations are within the scope of the following claims.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims.

As used herein, the terms comprises, comprising, or any other variation thereof, are intended to cover a non-exclusive inclusion, such that a process, method, article, or apparatus that comprises a list of elements does not include only those elements but may include other elements not expressly listed or inherent to such process, method, article, or apparatus. Further, no element described herein is required for the practice of the invention unless expressly described as essential or critical.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A semiconductor package, comprising:
a substrate having a first surface, a second surface opposing the first surface, and first bonding pads disposed on the second surface;
a first semiconductor chip having a third surface facing the second surface of the substrate, a fourth surface opposing the third surface, and first through-electrodes extending between the third and fourth surfaces, wherein respective ones of the first through-electrodes correspond to, and are electrically connected to, respective ones of the first bonding pads;
a first heat conductive layer plated onto the fourth surface, thereby providing a fifth surface;
a first insulating layer formed on the first heat conductive layer fifth surface, thereby providing a sixth surface, wherein the first heat conductive layer and first insulating layer form first vias, respective ones of the first vias surrounding respective ones of the first through-electrodes; and
a second semiconductor chip having a seventh surface facing the sixth surface of the first insulating layer of the first semiconductor chip, an eighth surface opposing the seventh surface, and second through-electrodes extending between the seventh and eighth surfaces, wherein respective ones of the second through-electrodes correspond to, and have electrical connections through the first vias to, respective ones of the first through-electrodes of the first semiconductor chip.

2. The semiconductor package of claim 1, comprising:
a second heat conductive layer plated onto the eighth surface of the second semiconductor chip, thereby providing a ninth surface;
a second insulating layer formed on the second heat conductive layer ninth surface, thereby providing a tenth surface, wherein the second heat conductive layer and second insulating layer form second vias, respective ones of the second vias surrounding respective ones of the second through-electrodes of the second semiconductor chip; and
a third semiconductor chip having an eleventh surface facing the tenth surface of the second insulating layer, a twelfth surface opposing the eleventh surface, and third through-electrodes extending between the eleventh and twelfth surfaces, wherein respective ones of the third through-electrodes have electrical connections through the second vias to respective ones of the second through-electrodes of the second semiconductor chip.

3. The semiconductor package of claim 2, comprising:
first conductive bumps bonded to respective ones of the first through-electrodes on the third surface of the first semiconductor chip, wherein the electrical connections of the first through-electrodes of the first semiconductor chip to the bonding pads of the substrate include bonds of the first conductive bumps to corresponding ones of the bonding pads;
second conductive bumps bonded to respective ones of the second through-electrodes on the seventh surface of the second semiconductor chip, wherein the electrical connections of the second through-electrodes of the second semiconductor chip to the first through-electrodes of the first semiconductor chip include bonds of the second conductive bumps in electrical contact through the first vias to corresponding ones of the first through-electrodes of first semiconductor chip;
third conductive bumps bonded to respective ones of the third through-electrodes on the eleventh surface of the second semiconductor chip, wherein the electrical connections of the third through-electrodes of the third semiconductor chip to the second through-electrodes of the second semiconductor chip include bonds of the third conductive bumps in electrical contact through the second vias to corresponding ones of the second through-electrodes of second semiconductor chip.

4. The semiconductor package of claim 3, wherein each semiconductor chip further has respective conductive capture pads electrically connected to respective through-electrodes of the semiconductor chip in each through-electrode's respective via.

5. The semiconductor package of claim 3, comprising:
films of an adhesive material on the respective surfaces of the semiconductor chips that have the conductive bumps thereon, wherein the respective films provide chip-to-chip and chip-to-substrate adhesion and provide air gaps between the conductive bumps and the vias.

6. The semiconductor package of claim 3, comprising:
underfill between the semiconductor chips and between the first semiconductor chip and the substrate, wherein the underfill provides chip-to-chip and chip-to-substrate adhesion.

7. The semiconductor package of claim 3, wherein the through-electrodes include copper pillars.

8. The semiconductor package of claim 3, wherein the plated heat conductive layer on each semiconductor chip includes a grounding portion and a source voltage portion, wherein at least one conductive bump of each semiconductor chip is connected to that semiconductor chip's grounding portion and one conductive bump of each semiconductor chip to that semiconductor chip's source voltage portion.

9. A method of providing a package of semiconductor chips, the method comprising:
plating a heat conductive layer on a first surface of a wafer of semiconductor chips, the wafer having a second surface opposing the first surface, wherein the first and second surfaces of the wafer provide first and second opposing surfaces for each semiconductor chip, and wherein the plating of the first surface of the wafer thereby plates the first surfaces of the respective semiconductor chips;
forming an insulating layer on the heat conductive layer;
etching the heat conductive layer, wherein each semiconductor chip has through-electrodes extending between the semiconductor chip's first and second surfaces and the etching includes etching vias that expose the through-electrodes on the first surface of each semiconductor chip; and
depositing conductive bumps on the through-electrodes on the second surface of each semiconductor chip;
dicing the semiconductor chips from the wafer; and
stacking a first, second and third one of the semiconductor chips wherein the conductive bumps of the second semiconductor chip electrically contact the through-electrodes of the first semiconductor chip through the vias of the first semiconductor chip and the conductive bumps of the third semiconductor chip electrically contact the through-electrodes of the second semiconductor chip through the vias of the second semiconductor chip.

10. The method of claim 9, comprising:
depositing conductive capture pads on the through-electrodes within the vias of each semiconductor chip;
depositing bonding pads on a substrate;
stacking the first, second and third semiconductor chips on the substrate;
bonding the conductive bumps of the first chip to the bonding pads; and
bonding the first semiconductor chip's capture pads to the second semiconductor chip's conductive bumps and the second semiconductor chip's capture pads to the third semiconductor chip's conductive bumps.

11. A method comprising:
placing a first semiconductor chip on a substrate having a first surface, a second surface opposing the first surface, and first bonding pads on the second surface, wherein the first semiconductor chip has a third surface, a fourth surface opposing the third surface, first through-electrodes extending between the third and fourth surfaces, and conductive bumps on the third surface, and wherein placing the first semiconductor chip on the substrate includes:
placing the first semiconductor chip with respective conductive bumps of the first semiconductor chip contacting respective ones of the first bonding pads,
wherein the method comprises:
attaching respective conductive bumps of the first semiconductor chip to respective ones of the first bonding pads;
placing a second semiconductor chip on the first semiconductor chip, wherein the first semiconductor chip further has a first heat conductive layer plated onto the fourth surface, thereby providing a fifth surface, and the first semiconductor chip further has a first insulating layer formed on the first heat conductive layer fifth surface, thereby providing a sixth surface, wherein the first heat conductive layer and first insulating layer form first vias, respective ones of the first vias exposing respective ones of the first through-electrodes of the first semiconductor chip, wherein the second semiconductor chip has a seventh surface, an eighth surface opposing the seventh surface, second through-electrodes extending between the seventh and eighth surfaces, and conductive bumps on the seventh surface, and wherein placing the second semiconductor chip on the first semiconductor chip includes:
placing the second semiconductor chip with respective conductive bumps of the second semiconductor chip in electrical contact with respective ones of the first semiconductor chip's through-conductors through the first vias,
wherein the method comprises:
attaching the second semiconductor chip to the first semiconductor chip such that respective conductive bumps of the second semiconductor chip maintain fixed electrical contact with the respective ones of the first semiconductor chip's through-conductors through the first vias.

12. The method of claim 11, comprising:
placing a third semiconductor chip on the second semiconductor chip, wherein the second semiconductor chip has a second heat conductive layer plated onto the eighth surface of the second semiconductor chip, thereby providing a ninth surface, a second insulating layer formed on the second heat conductive layer ninth surface, thereby providing a tenth surface, wherein the second heat conductive layer and second insulating layer form second vias, respective ones of the second vias surrounding respective ones of the second through-electrodes of the second semiconductor chip, wherein the third semiconductor chip has an eleventh surface, a twelfth surface opposing the eleventh surface, third through-electrodes extending between the eleventh and twelfth surfaces, and conductive bumps on the eleventh surface, and wherein placing the third semiconductor chip on the second semiconductor chip includes:
placing the third semiconductor chip such that respective ones of the third chip's conductive bumps are in electrical contact with respective ones of the second semiconductor chip's through-conductors exposed by the second vias,
wherein the method further comprises:
attaching the third semiconductor chip to the second semiconductor chip, including attaching such that respective ones of the third semiconductor chip's conductive bumps maintain fixed electrical contact with the respective ones of the second semiconductor chip's through-conductors exposed by the second vias.

13. The method of claim 11, wherein the method includes plating the heat conductive layer onto one surface of the semiconductor chips, etching to form the vias in the heat conductive layer and forming an insulating layer on the heat conductive layer.

14. The method of claim 12, wherein the first semiconductor chip further has respective conductive capture pads electrically connected to the respective first through-electrodes in the first vias, and wherein attaching the second semiconductor chip to the first semiconductor chip, includes:
attaching the second chip's conductive bumps to respective ones of the first semiconductor chip's capture pads, and
wherein the second semiconductor chip further has respective conductive capture pads electrically connected to the respective second through-electrodes in the second vias, and wherein attaching the third semiconductor chip to the second semiconductor chip, includes:
attaching the third chip's conductive bumps to respective ones of the second semiconductor chip's capture pads,

15. The method of claim 14, wherein the attaching of the first chip's conductive bumps to respective ones of the first bonding pads of the substrate, the attaching of the second chip's conductive bumps to respective ones of the first chip's capture pads and the attaching of the third chip's conductive bumps to respective ones of the second chip's capture pads includes attaching by thermo-compression of the conductive bumps.

16. The method of claim 15, wherein the chip's conductive bumps have a solder coating and wherein the attaching of the first chip's conductive bumps to respective ones of the first bonding pads of the substrate, the attaching of the second chip's conductive bumps to respective ones of the first chip's capture pads and the attaching of the third chip's conductive bumps to respective ones of the second chip's capture pads includes attaching by reflowing the solder of the conductive bumps.

17. The method of claim 13, wherein the method further comprises applying, before placing the semiconductor chips, respective films of an adhesive material to the respective surfaces of the semiconductor chips that have the conductive bumps thereon, such that the respective films provide chip-to-chip and chip-to-substrate adhesion and provide air gaps between the conductive bumps and the vias.

18. The method of claim 13, wherein the method further comprises applying underfill between the semiconductor chips and between the first semiconductor chip and the substrate, wherein the underfill provides chip-to-chip and chip-to-substrate adhesion.

19. The method of claim 11, including forming the through-electrodes by depositing copper pillars.

20. The method of claim 13, comprising:
etching the plated heat conductive layer to separate the heat conductive layer into at least a grounding portion and a source voltage portion and connecting at least one conductive bump of each semiconductor chip to the grounding portion and one conductive bump of each semiconductor chip to the source voltage portion.
